(19) United States
(12) Patent Application Publication
(10) Pub. No.: US 2009/0231822 A1
(43) Pub. Date: Sep. 17, 2009

(54) DEVICE, IN PARTICULAR INTELLIGENT POWER MODULE WITH PLANAR CONNECTION

(75) Inventors: Markus Fruhauf, Hessdorf/Untermembach (DE); Carsten Rebbereh, Fürth (DE)

Correspondence Address: HENRY M FEIEREISEN, LLC;HENRY M FEIEREISEN, 708 THIRD AVENUE, SUITE 1501, NEW YORK, NY, 10017, US

(73) Assignee: SIEMENS AKTIENGESELLSCHAFT, München (DE)

(21) Appl. No.: 11/568,058

(22) PCT Filed: Apr. 14, 2005
(86) PCT No.: PCT/EP2005/051645

§ 371 Date: Oct. 18, 2006

(30) Foreign Application Priority Data
Apr. 19, 2004 (DE) 10 2004 019 447.5

(51) Int. Cl. H05K 7/00

(52) U.S. Cl. 361/777

(57) ABSTRACT

The invention relates to a device (1), in particular an intelligent power module. Said device comprises a power component (3,4) and a control circuit for controlling the power component (3), said component and circuit being located on a substrate (2). A connection between the power component (3) and the control circuit contains a layer consisting of an electrically insulating material, said layer being located on the power component and the substrate (2) and a layer of electrically conductive material, which is located on the layer of electrically insulating material. The invention thus provides an intelligent power module (1), which can be produced in a more cost-effective and compact manner.

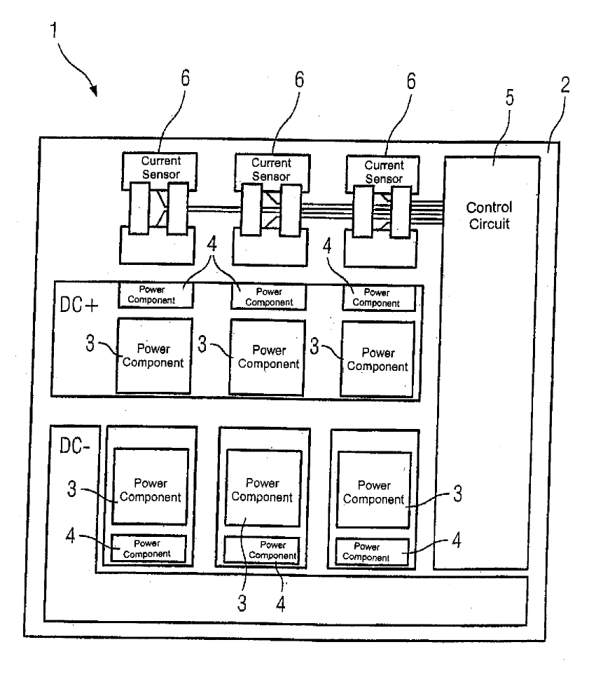

### BACKGROUND OF THE INVENTION

In new converter generations, an ever more compact structural form at higher ambient temperatures is demanded. To achieve a compact structural form, it is necessary to pack the necessary individual components more and more closely together. However, as a consequence it is necessary to insulate the high potentials from each other, in order to achieve sufficient air and leakage paths. The best way to achieve this seems to be the compact construction of an intelligent power module.

There are currently several solutions for this, each however entailing restrictions in one direction or another.

Thus, converters in conventional technology with a power semiconductor module, capacitors and components for electrical separation for activation and signal recording are put on a circuit board, in particular a printed circuit board (PCB), which is then painted with an insulating varnish to attain the compactness. However, this solution achieves only limited compactness and there are very high requirements for the insulating varnish and the processing.

Another possibility is the use of a so-called intelligent power module (IPM). The module manufacturer has already packed the essential functions in this. However, present-day intelligent power modules often have restrictions in the current measurement and in the potential of the secure electrical separation. There are essentially two solution approaches for constructing such modules. In the first, the individual components are disposed on a so-called lead frame, then the electrical connections are bonded, and after that everything is molded with a molding mass. The limits of this technology are in the current to be realized, and in the voltage to be achieved for the insulation.

In the second approach, the power semiconductors are constructed in a module, and in this the drive circuit is then further mounted, constructed in FR4 or ceramic. The contacting is normally by means of bonding. To meet the insulation requirements, everything is then potted with a silicone gel.

Known from WO 03/030247 A2 is a planar connection.

### SUMMARY OF THE INVENTION

Starting from that, the invention is based on the object of implementing intelligent power modules that can be manufactured more cheaply and more compactly.

This object is achieved by the inventions specified in the independent claims. Advantageous developments will become apparent from the claims.

Accordingly a device, in particular an intelligent power module, has a substrate, on which a power component and a control circuit for controlling this power component are disposed. The device further has a connection between the power component and the control circuit, this containing a layer of electrically insulating material, which is disposed on the power component and the substrate, and a layer of electrically conductive material, which is disposed on the layer of electrically insulating material.

Through the use of the planar connection, the advantage is thus derived that the power component and its control circuit can be disposed on the same substrate, giving a compact and cheaply manufactured power module that can be effectively cooled.

Through the substrate, which is a structured ceramic with copper surfaces, very high currents and voltages can be switched with the power module with the associated power dissipations.

The layer of electrically insulating material is advantageously a film, in particular a laminated film.

On the side facing away from the substrate the power component can have a contact area, on which the layer of electrically insulating material has a window and the layer of electrically conductive material is disposed.

The layer of electrically insulating material is advantageously on the power component, i.e. in particular its sides not disposed on the substrate, and on the substrate. This makes the device especially stable. The layer of electrically insulating material serves here as the substrate for the layer of electrically conductive material.

The control circuit preferably has a microprocessor, for example in the form of a microcontroller and/or logic chip.

In addition, the control circuit advantageously has means of current metering.

It is further advantageous if the control circuit has a transforming coupling, for coupling a control signal for the power component. The transforming coupling can be implemented, in particular as coreless, with two conductors running parallel, separated from each other by an insulator.

This can be implemented e.g. within a (silicon) component by means of a (silicon) oxide film,

Alternatively or in addition, the insulator is executed in the form of an insulating layer. This insulating layer can be provided for example by a film, laminated in particular, which is disposed between two electrically conductive layers for the transforming transmission, these being generated e.g. by electroplating. The transforming coupling can thus be manufactured in the same manner as the connection of the component, which means that its manufacture can be integrated excellently into the manufacturing process for the power module.

The control circuit preferably has a short-circuit protection, an excess temperature protection and/or an excess voltage protection.

The device can in particular also have a switched-mode mains power supply, in order to generate DC voltage, which is converted to AC voltage with the help of the power component. In particular, a transistor of this switched-mode mains power supply can also be disposed on the substrate, so that this can be cooled and connected in the same way as the power component.

Methods for manufacturing or operating a device of the aforementioned kind will emerge analogously to the device and/or from the following description of an embodiment.

### BRIEF DESCRIPTION OF THE DRAWING

Further advantages and features will follow from the description of the drawing. The FIGURE shows a power component with planar connection.

### DETAILED DESCRIPTION OF PREFERRED EMBODIMENTS

Shown in the FIGURE is a device 1, in particular an intelligent power module 1, which is constructed without bonding process and silicone potting. On a substrate 2, power components 3, e.g. IGBTs, and power components 4, e.g. diodes, are disposed.

Also disposed on the substrate 2 is a control circuit for the power components, containing electronic equipment 5, for example a microprocessor, and means 6 for current measurement, for example a shunt with driver including potential separation.

The substrate 2 is a copper-surface structured ceramic.

The potential separation to the signal transmission is effected in a preferred manner with component parts, with the potential separation realized with oxide films. This offers the advantage of being able to continue working permanently even at high temperatures, which is a fundamental requirement from the compactness.

The insulation and connection of the individual components is effected by putting on several electrically insulating and electrically conductive layers in the form of special film, and sputtered copper which is without external current and/or electrically deposited. Concerning the manufacture and properties of these layers, the full content of WO 03/030247 A2 is referenced. A layout of the structure emerges, which is comparable to a multilayered circuit board, which connects together the individual potentials.

The combination of the optimal insulation technology, which works well even at high temperatures, and the direct connection of the individual components on the ceramic with the planar connection, leads to an extremely compact package for the integrated power module 1. The same properties are achieved as in the layout of a converter 5 with power semiconductors and FR4 module with the components for secure electrical separation.

1. A device comprising
a substrate;
a power component disposed on the substrate;
a control circuit disposed on the substrate for controlling the power component; and
a connection between the power component and the control circuit, said connection comprising
a first layer made of electrically insulating material and disposed on the power component and the substrate, and
a second layer made of electrically conductive material and disposed on the first layer.

2. The device of claim 1, wherein the substrate is a structured ceramic with copper surfaces.

3. The device of claim 1, wherein the first layer of electrically insulating material is a thin film.

4. The device of claim 1, wherein the power component has a contact area on a side facing away from the substrate, the first layer having a window adjacent to the contact area, and the second layer overlaying the window to contact the contact area.

5. The device of claim 1, wherein the first layer fits closely on the power component and the substrate.

6. The device of claim 1, wherein the control circuit includes an electronic equipment.

7. The device of claim 1, wherein the control circuit includes means for metering an electric current.

8. The device of claim 1, wherein the control circuit has a transformer coupling for coupling a control signal to the power component.

9. The device of claim 8, wherein the transformer coupling is implemented with two conductors running parallel and separated from each other by an insulator.

10. The device of claim 9, wherein the insulator includes an oxide film.

11. The device of claim 9, wherein the insulator includes an insulating layer.

12. The device of claim 1, wherein the control circuit includes at least one of a short-circuit protection, an excess temperature protection and an excess voltage protection.

13. The device of claim 1, further comprising a switched mode mains power supply to generate DC voltage.

14. The device claim 13, wherein the switched mode mains power supply includes a transistor disposed on the substrate.

15. A method for manufacturing or operating a device as set forth in claim 1.

16. The device of claim 9, wherein the transformer coupling is constructed in the absence of a transformer core.
